(19) United States
(12) Patent Application Publication
(10) Pub. No.: US 2024/0421617 A1
(43) Pub. Date: Dec. 19, 2024

(54) AUTOMOTIVE INTEGRATED CIRCUIT

(71) Applicant: ROHM CO., LTD., Kyoto-shi (JP)

(72) Inventor: Mitsuteru SAKAI, Kyoto-shi (JP)

(21) Appl. No.: 18/814,991

(22) Filed: Aug. 26, 2024

Related U.S. Application Data
(63) Continuation of application No. PCT/JP2023/005294, filed on Feb. 15, 2023.

(30) Foreign Application Priority Data
Feb. 28, 2022 (JP) 2022-029436

(51) Int. Cl. H02J 7/00; H02H 9/04; H02H 11/00; H03F 3/217

(52) U.S. Cl. CPC H02J 7/0034; H02H 9/042; H02H 11/003; H03F 3/217; H02J 7/00302; H02J 7/00308; H03F 2200/03; H03F 2200/351; H03F 2200/78

(57) ABSTRACT

A constant voltage circuit stabilizes a voltage V that occurs at a capacitor connection terminal. An internal circuit operates based on the voltage that occurs at the capacitor connection terminal. A first voltage dividing circuit generates a first voltage, which is obtained by dividing the power supply voltage that occurs at the power supply terminal, at the capacitor connection terminal. A charging transistor is arranged with one end coupled to the capacitor connection terminal. A second voltage dividing circuit generates a second voltage obtained by dividing the power supply voltage at a control terminal of the charging transistor. A clamp circuit clamps the voltage that occurs at the capacitor connection terminal and the voltage at the control terminal of the charging transistor so as to prevent them from exceeding a limit voltage.

### CROSS REFERENCE TO RELATED APPLICATIONS

This application is a continuation under 35 U.S.C. § 120 of PCT/JP2023/005294, filed Feb. 15, 2023, which is incorporated herein by reference, and which claimed priority to Japanese Application No. 2022-029436, filed Feb. 28, 2022. The present application likewise claims priority under 35 U.S.C. § 119 to Japanese Application No. 2022-029436, filed Feb. 28, 2022, the entire content of which is also incorporated herein by reference.

### BACKGROUND

### 1. Technical Field

The present disclosure relates to an automotive integrated circuit.

### 2. Description of the Related Art

Known examples of a semiconductor integrated circuit (automotive integrated circuit) to be used in an in-vehicle audio system, car navigation system, or other in-vehicle electronic devices include a semiconductor integrated circuit configured to operate by directly receiving a battery voltage from a battery. Such an in-vehicle battery greatly fluctuates from its rated voltage (e.g., 14.4 V) during use. Accordingly, such a semiconductor integrated circuit is required to operate normally even in a severe environment in which the battery voltage greatly fluctuates. In order to solve such a problem, before shipping, the performance of such a semiconductor integrated circuit is tested by means of a load dump test, cold crank test, or the like. For example, in a load dump test, an overvoltage in the vicinity of 40 V is transiently applied to a power supply terminal of the semiconductor integrated circuit.

With an arrangement in which the semiconductor integrated circuit is formed of high-withstand-voltage elements such as DMOSs (Double-Diffused MOSs) that are capable of withstanding even 40 V, this is capable of providing performance that passes the load dump test. However, such a high-withstand-voltage element has a large element size as compared with a low-withstand-voltage element. This leads to an increased semiconductor integrated circuit chip area, leading to increased costs.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram of a system provided with an automotive integrated circuit according to an embodiment 1,

FIG. 2 is a circuit diagram of a system provided with an automotive integrated circuit according to an embodiment 1,

FIG. 3 is an operation waveform diagram of the automotive integrated circuit shown in FIG. 2 in the startup operation,

FIG. 4 is an operation waveform diagram of the automotive integrated circuit shown in FIG. 2 in the startup operation,

FIG. 5 is a circuit diagram showing an example configuration of a clamp circuit,

FIG. 6 is a circuit diagram of a system provided with an automotive integrated circuit according to an embodiment 2,

FIG. 7 is a circuit diagram showing an example configuration of a second regulator shown in FIG. 6,

FIG. 8 is a circuit diagram of an audio system provided with an audio circuit,

FIG. 9 is a circuit diagram showing an example configuration of a linear regulator and buffer shown in FIG. 8; and

FIG. 10 is a block diagram of an in-vehicle audio system using an audio circuit according to an embodiment.

### DETAILED DESCRIPTION

### Outline of Embodiments

Description will be made regarding the outline of several exemplary embodiments of the present disclosure. The outline is a simplified explanation regarding several concepts of one or multiple embodiments as a preface to the detailed description described later in order to provide a basic understanding of the embodiments. That is to say, the outline described below is by no means intended to restrict the scope of the present invention and the present disclosure. The outline is by no means a comprehensive outline of all possible embodiments. That is to say, the outline is by no means intended to identify the indispensable or essential elements of all the embodiments and is by no means intended to define the scope of a part of or all the embodiments. For convenience, in some cases, an “embodiment” as used in the present specification represents a single or multiple embodiments (examples and modifications) disclosed in the present specification.

An automotive integrated circuit according to one embodiment includes: a power supply terminal to be coupled to a battery; a capacitor connection terminal to be coupled to an external capacitor; a constant voltage circuit structured to stabilize a voltage that occurs at the capacitor connection terminal; and an internal circuit structured to operate based on the voltage that occurs at the capacitor connection terminal. The constant voltage circuit includes: a first voltage dividing circuit having an input node coupled to the power supply terminal and an output node coupled to the capacitor connection terminal, structured to generate a first voltage, which is obtained by dividing the power supply voltage that occurs at the power supply terminal, at the capacitor connection terminal; a charging transistor with one end coupled to the capacitor connection terminal; a second voltage dividing circuit having an input node coupled to the power supply terminal and an output node coupled to a control terminal of the charging transistor, structured to generate a second voltage obtained by dividing the power supply voltage at the control terminal of the charging transistor; and a clamp circuit structured to clamp the voltage generated at the capacitor connection terminal and the voltage at the control terminal of the charging transistor.

With this configuration, the charging transistor and the second voltage dividing circuit form a charging circuit. This arrangement is capable of charging a capacitor coupled to the capacitor connection terminal via the charging transistor in a short period of time when the circuit is started up. With such an arrangement in which the clamp circuit clamps the control terminal of the charging transistor in addition to the capacitor connection terminal, in a case in which an overvoltage is applied as the power supply voltage, this is capable of suppressing overcharging of the capacitor connection terminal via the charging transistor.

In one embodiment, the clamp circuit may include: a first transistor having an emitter coupled to the output node of the first voltage dividing circuit; a second transistor having an emitter coupled to the output node of the second voltage dividing circuit; and a first regulator circuit structured to apply a predetermined voltage to a base of each of the first transistor and the second transistor.

In one embodiment, the first transistor and the second transistor may each be structured as a Darlington transistor.

In one embodiment, the first regulator circuit may include: an operational amplifier structured to receive a reference voltage via a non-inverting input terminal; a first resistor coupled between an output of the operational amplifier and an inverting input terminal thereof; and a second resistor coupled between the inverting input terminal of the operational amplifier and the ground.

In one embodiment, the internal circuit may include an audio amplifier structured to operate with a voltage that occurs at the capacitor connection terminal as a reference, so as to amplify an audio signal.

In one embodiment, the automotive integrated circuit may further include a second regulator circuit arranged having an input node coupled to the power supply terminal and an output node coupled to the other end of the charging transistor and structured to output an internal power supply voltage stabilized to a predetermined voltage level. This allows the automotive integrated circuit to be designed with a charging transistor having a reduced withstand voltage.

In one embodiment, the second regulator circuit may include: a third transistor arranged with one end coupled to the input node of the second regulator circuit and with the other end coupled to the output node of the second regulator circuit; a third resistor coupled between the output node of the second regulator and the ground; a first Zener diode coupled between a gate and source of the third transistor; and a bias circuit structured to apply a constant voltage to a gate of the third transistor.

In one embodiment, the bias circuit may include: a fourth resistor coupled between the input node of the second regulator circuit and the gate of the third transistor; and multiple second Zener diodes coupled in series between the gate of the third transistor and the ground. With such an arrangement in which the second regulator circuit is configured in a simple manner, this allows an increase of the circuit area to be suppressed.

In one embodiment, the other end of the charging transistor may be coupled to the power supply terminal. In this case, the charging transistor is required to be configured as a high-withstand-voltage element. However, such an arrangement requires no second regulator circuit.

In one embodiment, the audio amplifier may be structured as a Class-D amplifier circuit. Also, the internal circuit may further include a linear regulator structured to generate a first power supply voltage with a voltage that occurs at the capacitor connection terminal as a reference. Also, the Class-D amplifier circuit may include: an inverter-type output stage structured to receive a supply of the power supply voltage; an integrator structured to receive a supply of the first power supply voltage, and to receive a feedback signal that corresponds to an input audio signal and an output signal of the output stage; a comparator structured to receive a supply of the first power supply voltage, and to convert an output of the integrator into a PWM signal; and a driver structured to receive a supply of a second power supply voltage that is lower than the power supply voltage and the first power supply voltage, and to drive the output stage based on an output of the comparator.

An in-vehicle battery may be coupled to the power supply terminal. The in-vehicle battery supplies an unstable voltage. Accordingly, severe performance tests are applied to the automotive integrated circuit. With this embodiment, such an arrangement is capable of withstanding a fluctuation of the battery voltage.

### EMBODIMENTS

Description will be made below regarding preferred embodiments with reference to the drawings. The same or similar components, members, and processes are denoted by the same reference numerals, and redundant description thereof will be omitted as appropriate. The embodiments have been described for exemplary purposes only and are by no means intended to restrict the present disclosure and the present invention. Also, it is not necessarily essential for the present disclosure and the present invention that all the features or a combination thereof be provided as described in the embodiments.

In the present specification, a state represented by the phrase “the member A is coupled to the member B” includes a state in which the member A is indirectly coupled to the member B via another member that does not substantially affect the electric connection between them, or that does not damage the functions or effects of the connection between them, in addition to a state in which they are physically and directly coupled.

Similarly, a state represented by the phrase “the member C is coupled (provided) between the member A and the member B” includes a state in which the member A is indirectly coupled to the member C, or the member B is indirectly coupled to the member C via another member that does not substantially affect the electric connection between them, or that does not damage the functions or effects of the connection between them, in addition to a state in which they are directly coupled.

### Embodiment 1

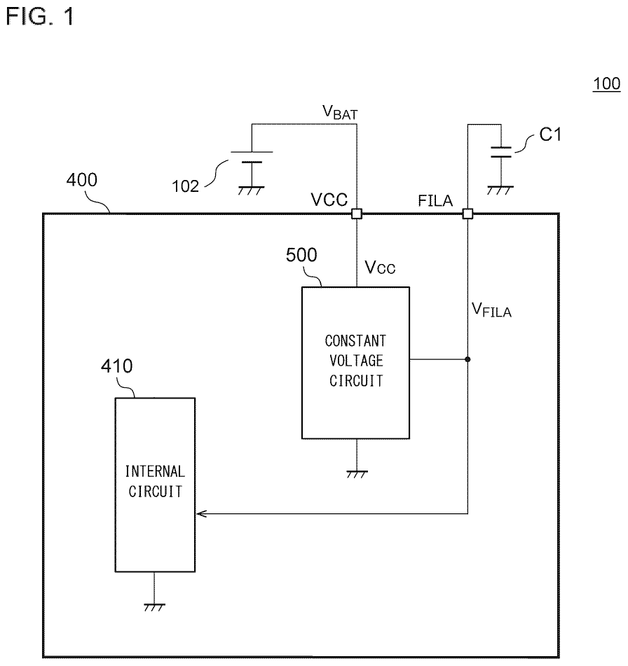

FIG. 1 is a circuit diagram of a system 100 provided with an automotive integrated circuit 400 according to an embodiment 1. A power supply terminal (power supply pin) VCC of the automotive integrated circuit 400 is coupled to an in-vehicle battery (which will simply be referred to as a “battery”) 102. The automotive integrated circuit 400 operates with an external power supply voltage (which will simply be referred to as a “battery voltage”) V_{CC} based on the battery voltage V_{BAT} as a power supply. In a case in which a 12-V battery is employed, a battery voltage on the order of 10 to 14 V can be supported. In a case in which a 24-V battery is employed, a battery voltage on the order of 18 to 30 V can be supported.

A capacitor connection terminal FILA of the automotive integrated circuit 400 is coupled to an external capacitor C1. The automotive integrated circuit 400 includes an internal circuit 410 and a constant voltage circuit 500. The constant voltage circuit 500 has an input node coupled to the power supply terminal VCC, and an output node coupled to the capacitor connection terminal FILA. The constant voltage circuit 500 stabilizes the voltage V_{FILA} that occurs at the capacitor connection terminal FILA to a voltage level obtained by dividing the power supply voltage V_{CC} with a voltage dividing ratio α (0<α<1).

The internal circuit 410 operates with the voltage V_{FILA} at the capacitor connection terminal FILA as a reference. Accordingly, the voltage V_{FILA} will also be referred to as a “reference voltage”. In the present disclosure, the function and configuration of the internal circuit 410 are not restricted in particular.

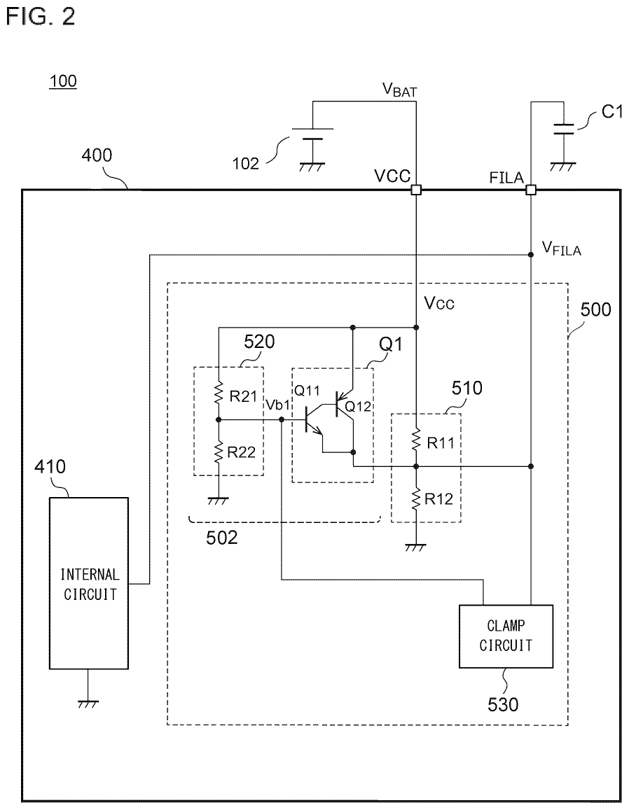

FIG. 2 is a circuit diagram of the system 100 provided with the automotive integrated circuit 400 according to the embodiment 1. The constant voltage circuit 500 includes a charging transistor Q1, a first voltage dividing circuit 510, a second voltage dividing circuit 520, and a clamp circuit 530.

The first voltage dividing circuit 510 is arranged with an input node coupled to the power supply terminal VCC, and with an output node coupled to the capacitor connection terminal FILA. The first voltage dividing circuit 510 generates a reference voltage (first voltage) V_{FILA}, which is obtained by dividing the power supply voltage V_{CC} with the voltage dividing ratio α, at the capacitor connection terminal FILA.

$$\begin{matrix}{V}_{FILA} = {V}_{CC} \times R 12 / ( R 11 + R 12 ) \\ α = R 12 / ( R 11 + R 12 )\end{matrix}$$

The charging transistor Q1 and the second dividing circuit 520 form a charging circuit 502. The charging transistor Q1 is arranged with one end (emitter) coupled to the capacitor connection terminal FILA. The other end (collector) of the charging transistor Q1 is coupled to the power supply terminal VCC. In the present embodiment, the charging transistor Q1 is configured as a Darlington transistor including an NPN bipolar transistor Q11 and a PNP bipolar transistor Q12.

The second voltage dividing circuit 520 is arranged with an input node coupled to the power supply terminal VCC and an output node coupled to the base that is a control terminal of the charging transistor Q1. The second voltage dividing circuit 520 supplies a second voltage Vb1 (=V_{CC}×β), which is obtained by dividing the power supply voltage V_{CC} with a predetermined voltage dividing ratio β (0<β<1), to the control terminal (base) of the charging transistor Q1.

$$\begin{matrix}V b 1 = {V}_{CC} \times R 22 / ( R 21 + R 22 ) \\ β = R 22 / ( R 21 + R 22 )\end{matrix}$$

The clamp circuit 530 is coupled to an output node of the second voltage dividing circuit 520 (i.e., the base of the charging transistor Q1) and an output node of the first voltage dividing circuit 510 (i.e., the capacitor connection terminal FILA). The clamp circuit 530 clamps the output voltage Vb1 of the second voltage dividing circuit 520 and the reference voltage V_{FILA} such that they do not exceed a limit voltage V_{LIM}. The limit voltage V_{LIM} may preferably be determined giving consideration to the withstand voltage of the internal circuit 410.

The above is the configuration of the in-vehicle semiconductor circuit 400. Next, description will be made regarding the operation thereof.

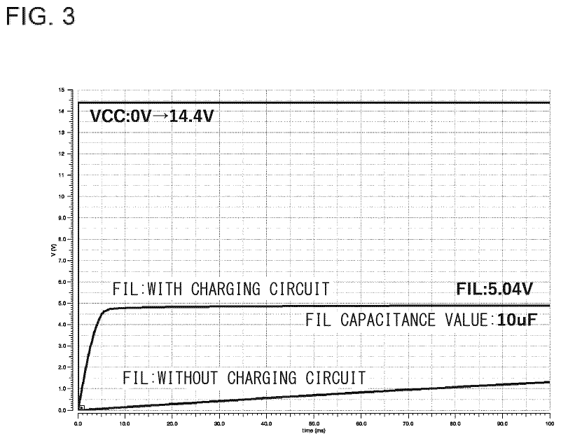

FIG. 3 is an operation waveform diagram (simulation results) of the automotive integrated circuit 400 shown in FIG. 2 in the startup operation. FIG. 3 shows the reference voltage V_{FILA} in a case with the charging circuit 502, and in a case without the charging circuit 502. V_{CC} rises from 0 V to 14.4 V. The capacitor C1 is designed with a capacitance value of 10 μF. Furthermore, description will be made assuming that R11=93.6 kΩ, R12=50.4 kΩ, R21=89.6 kΩ, and R22=54.4 kΩ.

First, description will be made regarding a case without the charging circuit 502. In this case, the capacitor C1 is charged via the resistor R11 of the first voltage dividing circuit 510. The reference voltage V_{FILA} rises with a time constant determined by the resistor R11 and the capacitor C1. In this example, a long period of time of 751.2 ms is required until the reference voltage V_{FILA} reaches 90% of the target voltage of 5.04 V.

In contrast, with the automotive integrated circuit 400 with the charging circuit 502 shown in FIG. 2, when the power supply voltage V_{CC} rises, the capacitor C1 coupled to the capacitor connection terminal FILA is charged using a current that flows through the charging transistor Q1.

The voltage dividing ratio α of the first voltage dividing circuit 510 and the voltage dividing ratio β of the second voltage dividing circuit 520 are determined so as to satisfy V_{CC}×β−Vbe<V_{CC}×α.

The reference voltage V_{FILA} is rapidly charged to the vicinity of Vb1−Vbe. Here, Vbe represents the base-emitter voltage of the transistor Q11. Subsequently, after completion of the rapid charging by the charging circuit 502, the capacitor C1 coupled to the capacitor connection circuit FILA is charged to (V_{CC}×α).

With the automotive integrated circuit 400 shown in FIG. 2, this requires a period of time of only 4.6 ms until the reference voltage V_{FILA} reaches 90% of 5.04 V, which is 1/100 or less the time required in a case without the charging circuit 502.

Next, description will be made regarding the operation when an overvoltage is applied as the power supply voltage V_{CC}.

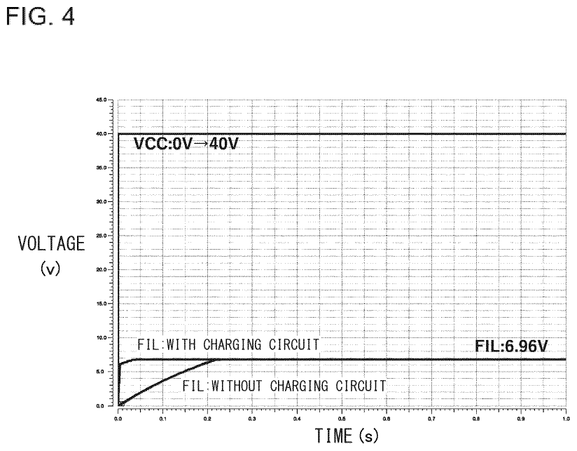

FIG. 4 is an operation waveform diagram (simulation results) of the automotive integrated circuit 400 shown in FIG. 2 in the startup operation. This drawing shows the operation when the power supply voltage V_{CC} rises to 40 V. For comparison, FIG. 4 also shows the reference voltage V_{FILA} in a case without the charging circuit 502.

In this example, the limit voltage V_{LIM} is set to 6.96 V. The reference voltage V_{FILA} that occurs across the capacitor C1 is clamped such that it does not exceed 6.96 V after the reference voltage V_{FILA} is rapidly charged to 6.96 V.

In this example, the clamp circuit 530 clamps the voltage Vb1 at the output node of the second voltage dividing circuit 520 (base of the charging transistor Q1) in addition to the reference voltage V_{FILA}. If the clamp circuit 530 clamps only the capacitor connection terminal FILA, the supply of the charging current Q1 will continue from the charging transistor Q1 to the FILA terminal, leading to wasted current consumption. In contrast, with the configuration shown in FIG. 2, the base voltage Vb1 of the charging transistor Q1 is clamped by the clamp circuit 530. With this, in the overvoltage state, the charging transistor Q1 is turned off, thereby cutting off the charging current. This allows wasted power consumption to be suppressed.

The above is the operation of the automotive integrated circuit 400 when an overvoltage input is supplied. With the automotive integrated circuit 400, the charging circuit 502 allows the reference voltage V_{FILA} to be stabilized in a short period of time, thereby allowing the circuit startup time to be dramatically reduced. Furthermore, in a case in which an overvoltage is supplied as the power supply voltage V_{CC} due to an increased battery voltage V_{BAT}, this is capable of suppressing the supply of the overvoltage to the internal circuit 410.

The present disclosure encompasses various kinds of apparatuses and methods that can be regarded as a block configuration or a circuit configuration shown in FIG. 2, or otherwise that can be derived from the aforementioned description. That is to say, the present disclosure is not restricted to a specific configuration. More specific description will be made below regarding example configurations or examples for clarification and ease of understanding of the essence of the present disclosure and the present invention and the operation thereof. That is to say, the following description will by no means be intended to restrict the technical scope of the present disclosure.

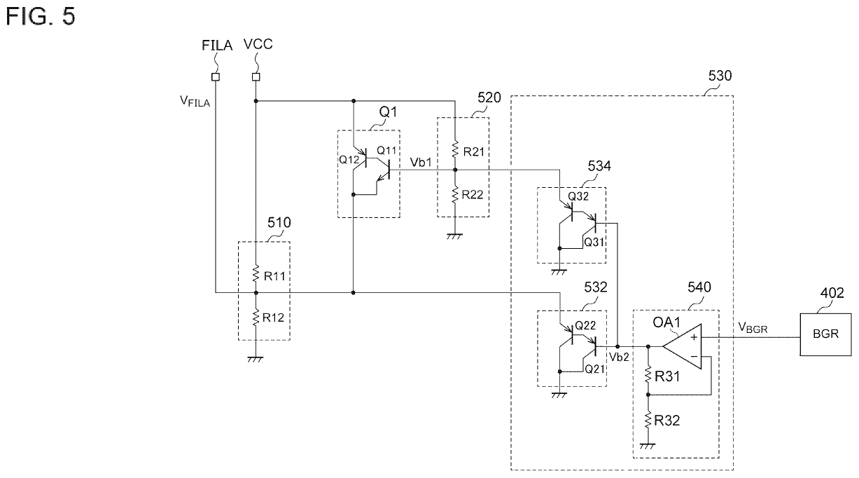

FIG. 5 is a circuit diagram showing an example configuration of the clamp circuit 530. The clamp circuit 530 includes a first transistor 532, a second transistor 534, and a first regulator circuit 540.

The first transistor 532 is arranged with its emitter coupled to the output node of the first voltage dividing circuit 510, i.e., the capacitor connection terminal FILA. The first transistor 532 is configured as a Darlington transistor including PNP transistors Q21 and Q22.

Furthermore, the second transistor 534 is arranged with its emitter coupled to the output node of the second voltage dividing circuit 520, i.e., the base of the charging transistor Q1. The second transistor 534 is configured as a Darlington transistor including PNP transistors Q31 and Q32.

It should be noted that the first transistor 532 and the second transistor 534 are each not restricted to such a Darlington transistor. Also, they may each be configured as a single PNP bipolar transistor.

The first regulator circuit 540 applies a predetermined voltage Vb2 to the base of each of the first transistor 532 and the second transistor 534. The limit voltage V_{LIM} is represented by the following Expression.

$${V}_{LIM} = V b 2 + 2 \times V be$$

The first regulator circuit 540 includes an operational amplifier OA1, a first resistor R31, and a second resistor R32. The first regulator circuit 540 receives the reference voltage V_{BGR} from a bandgap reference circuit 402. The reference voltage V_{BGR} is input to the non-inverting input terminal (+) of the operational amplifier OA1. The first resistor R31 is coupled between the output and the inverting input terminal (−) of the operational amplifier OA1. The second resistor R32 is coupled between the inverting input terminal (−) of the operational amplifier OA1 and the ground. The output voltage Vb2 of the first regulator circuit 540 is represented by the following Expression.

$$V b 2 = {V}_{BGR} \times ( R 31 + R 32 ) / R 32$$

It should be noted that the configuration of the first regulator circuit 540 is not restricted to such an arrangement shown in FIG. 5. Also, the first regulator circuit 540 may be configured as a known regulator circuit or constant voltage circuit.

### Embodiment 2

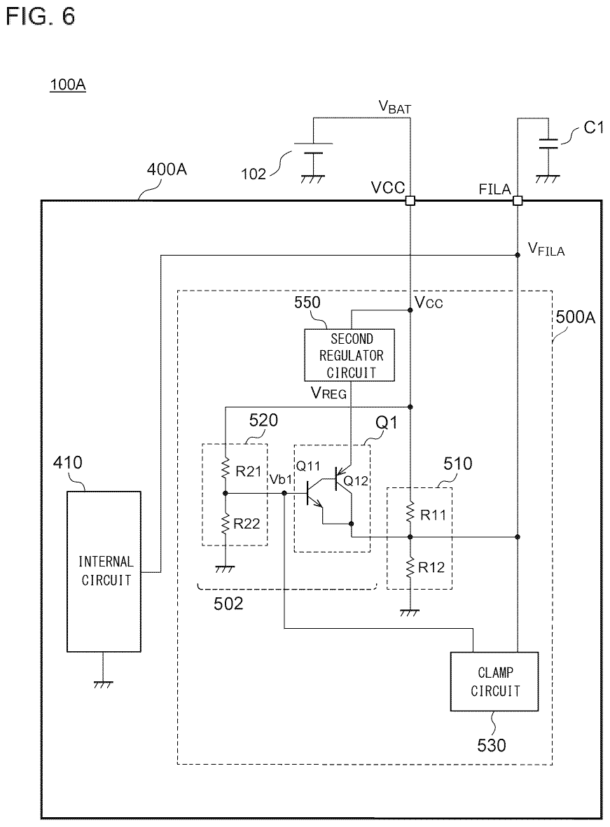

FIG. 6 is a circuit diagram of a system 100A provided with an automotive integrated circuit 400A according to an embodiment 2. A constant voltage circuit 500A further includes a second regulator circuit 550 in addition to the constant voltage circuit 500 shown in FIG. 2.

The second regulator circuit 550 is arranged with an input node coupled to the power supply terminal VCC and an output node coupled to the collector of the charging transistor Q1. The second regulator circuit 550 supplies an internal power supply voltage V_{REG} stabilized to a predetermined voltage level to the collector of the charging transistor Q1. The voltage level of the internal power supply voltage V_{REG} is defined to be higher than the reference voltage V_{FILA} when the power supply voltage V_{CC} is set to a normal voltage level (<14.4 V). For example, the internal power supply voltage V_{REG} may be designed to have a voltage level on the order of 9 V.

In the automotive integrated circuit 400 shown in FIG. 2, the power supply voltage V_{CC} is directly applied to the collector of the charging transistor Q1. Accordingly, it is necessary to configure the charging transistor Q1 as an element having a high withstand voltage of 40V.

In contrast, with the automotive integrated circuit 400A shown in FIG. 6, the second regulator circuit 550 allows the collector voltage of the charging transistor Q1 to be employed as the internal power supply voltage V_{REG}, thereby allowing the withstand voltage of the charging transistor Q1 to be reduced. This allows the circuit area of the charging transistor Q1 to be reduced.

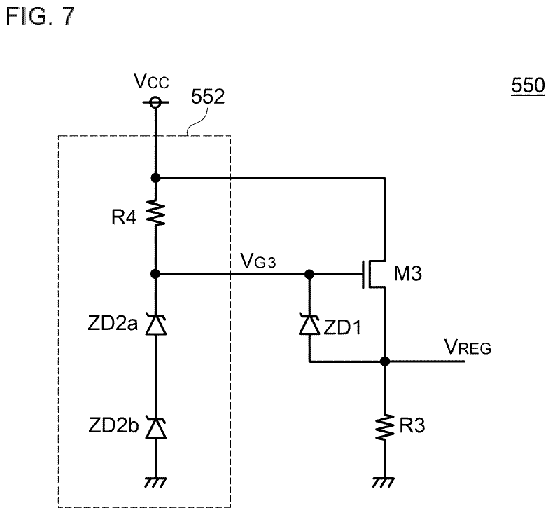

FIG. 7 is a circuit diagram showing an example configuration of the second regulator circuit 550 shown in FIG. 6. The second regulator circuit 550 includes a third transistor M3, a third resistor R3, a first Zener diode ZD1, and a bias circuit 552.

The third transistor M3 is configured as an N-channel MOSFET with one end (drain) coupled to the input node of the second regulator circuit 550, and with the other end (source) coupled to the output node of the second regulator circuit 550. The third resistor R3 is coupled between the output node of the second regulator circuit 550 and the ground. The first Zener diode ZD1 is coupled between the gate and the source of the third transistor M3. The bias circuit 552 applies a constant voltage V_{G3} to the gate of the third transistor M3.

The bias circuit 552 includes a fourth resistor R4 and multiple second Zener diodes ZD2a and ZD2b. The fourth resistor R4 is coupled between the input node of the second regulator circuit 550 and the gate of the third transistor M3. The multiple second Zener diodes ZD2a and ZD2b are coupled in series between the gate of the third transistor M3 and the ground. The constant voltage V_{G3} is represented by the following Expression.

$${V}_{G 3} = 2 \times {V}_{ZD}$$

Here, V_{ZD} represents a Zener voltage.

The output voltage V_{REG} of the second regulator circuit 550 is represented by V_{REG}=V_{ZD}.

The second regulator circuit 550 shown in FIG. 7 employs a simple constant voltage circuit that does not use an operational amplifier, thereby allowing an increase of the circuit area to be suppressed. It should be noted that the second regulator may be configured as a linear regulator using an operational amplifier in the same manner as with the first regulator circuit 540 shown in FIG. 5.

### Usage

Next, description will be made regarding the usage of the automotive integrated circuit 400. Examples of the usage of the automotive integrated circuit 400 include an in-vehicle audio circuit.

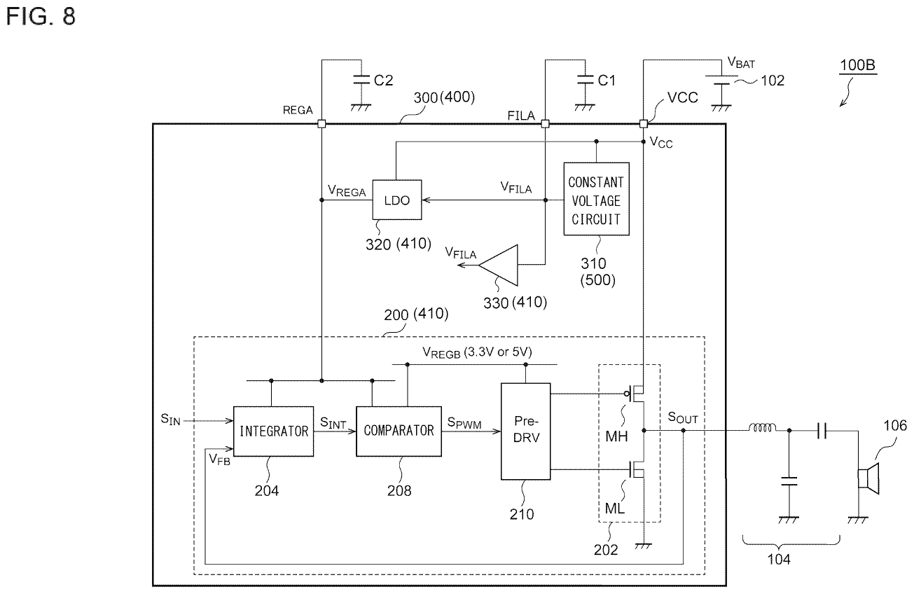

FIG. 8 is a circuit diagram of an audio system 100B provided with an audio circuit 300. The audio circuit 100B includes a battery 102, a filter 104, a speaker 106, and an audio circuit 300.

The audio circuit 300 includes a constant voltage circuit 310, a linear regulator 320, a buffer 330, and a Class D amplifier circuit 200. The audio circuit 300 corresponds to the automotive integrated circuit 400 shown in FIG. 2. The constant voltage circuit 310 corresponds to the constant voltage circuit 500 shown in FIG. 2. The linear regulator 320, the buffer 330, and the Class-D amplifier circuit 200 correspond to the internal circuit 410 shown in FIG. 2.

The output of the linear regulator 320 is coupled to an external smoothing capacitor C2 via a capacitor connection pin REGA. The linear regulator 320 receives the reference voltage V_{FILA}, and generates a first power supply voltage V_{REGA} having a voltage level obtained by multiplying the reference voltage V_{FILA} by a predetermined gain (×g). The first power supply voltage V_{REGA} is supplied as a power supply voltage to the Class-D amplifier circuit 200.

$${V}_{REGA} = g \times {V}_{FILA}$$

The buffer 330 receives the reference voltage V_{FILA} and supplies the reference voltage V_{FILA} to the Class-D amplifier circuit 200. The reference voltage V_{FILA} defines the center voltage level of the audio signal amplified by the Class-D amplifier circuit 200.

The Class-D amplifier circuit 200 receives an input audio signal S_{IN} and generates a pulse signal S_{OUT} having a duty ratio that corresponds to the input audio signal S_{IN}. The Class-D amplifier circuit 200 includes an output stage 202, an integrator 204, a comparator with a level-shift function (which will simply be referred to as a “comparator” hereafter) 208, and a pre-driver 210, which are integrated in the audio circuit 300. FIG. 8 shows only a one-channel configuration. In actuality, multiple channels of the Class-D amplifier circuit 200 are integrated in the audio circuit 300.

The power supply voltage V_{CC} is supplied to the inverter-type output stage 202. The output stage 202 is configured as an inverter including a high-side transistor MH and a low-side transistor ML. The output signal S_{OUT} of the output stage 202 swings between 0 V and V_{CC}. The output signal S_{OUT} is supplied to the speaker 106 via the filter 104.

The integrator 204 receives the supply of the first power supply voltage V_{REGA} generated by the linear regulator 320. The integrator 204 receives the input audio signal S_{IN} and a feedback signal S_{FB} that corresponds to the output signal S_{OUT} of the output stage 202. The integrator 204 integrates a signal that corresponds to the difference (error) between them.

The comparator 208 converts the output S_{INT} of the integrator 204 into a PWM signal S_{PWM}. The input stage of the comparator 208 operates with the first power supply voltage V_{REGA}. On the other hand, the output stage thereof receives the supply of a second power supply voltage V_{REGB} (e.g., 3.3 V or 5 V) that is lower than the power supply voltage V_{CC} and the first power supply voltage V_{REGA}. The comparator 208 outputs the PWM signal S_{PWM} that exhibits the binary value of 0 V or V_{REGB}.

The second power supply voltage V_{REGB} is supplied to the pre-driver 210. The pre-driver 210 drives the output stage 202 based on the output S_{PWM} of the comparator 208.

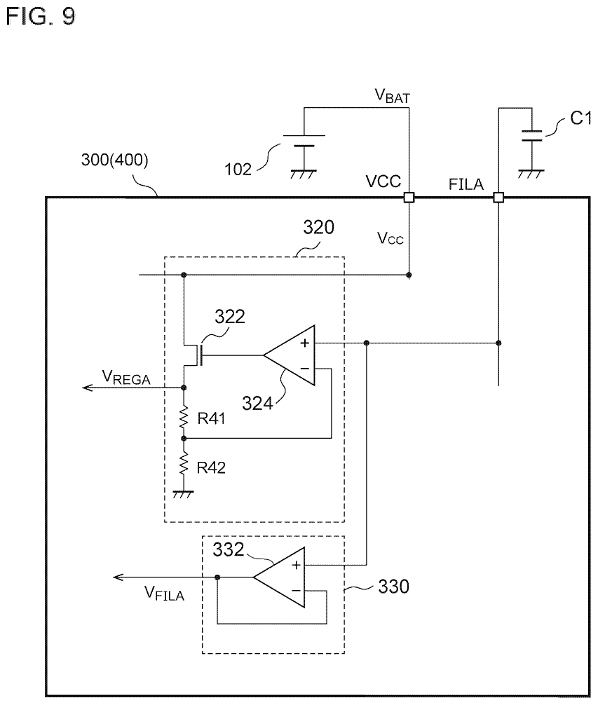

FIG. 9 is a circuit diagram showing an example configuration of the linear regulator 320 and the buffer 330 shown in FIG. 8. The linear regulator 320 includes a transistor 322, resistors R41 and R42, and an operational amplifier 324. The target voltage V_{REGA(REF)} of the first power supply voltage V_{REGA} is represented by Expression (1).

$${V}_{REGA ( REF )} = ( R 41 + R 42 ) / R 42 \times {V}_{FILA} \qquad ( 1 )$$

That is to say, the gain g of the linear regulator 320 is represented by (R41+R42)/R42.

In a situation in which the rated battery voltage V_{BAT(TYP)} is supplied, the gain g of the linear regulator 320 may preferably be designed to be as high as possible within a range in which the target voltage V_{REGA(REF)} does not exceed the power supply voltage V_{CC}. Specifically, in a case in which the voltage dividing ratio α of the first voltage dividing circuit 510 is designed to be d=R12/(R11+R12), the gain g may be designed in a range of 0.8<d×g<1. For example, in a case in which d=0.5 and g=1.8, V_{REGA(REF)}=13 V when V_{BAT(TYP)}=14.4 V.

In this example, the transistor 322 is configured as an NMOS transistor. However, the present invention is not restricted to such an arrangement. For example, the transistor 322 may be configured as a PMOS transistor. In this case, the inverting input terminal and the non-inverting input terminal may be swapped.

The buffer 330 includes an operational amplifier 332 with an output coupled to an inverting input terminal thereof.

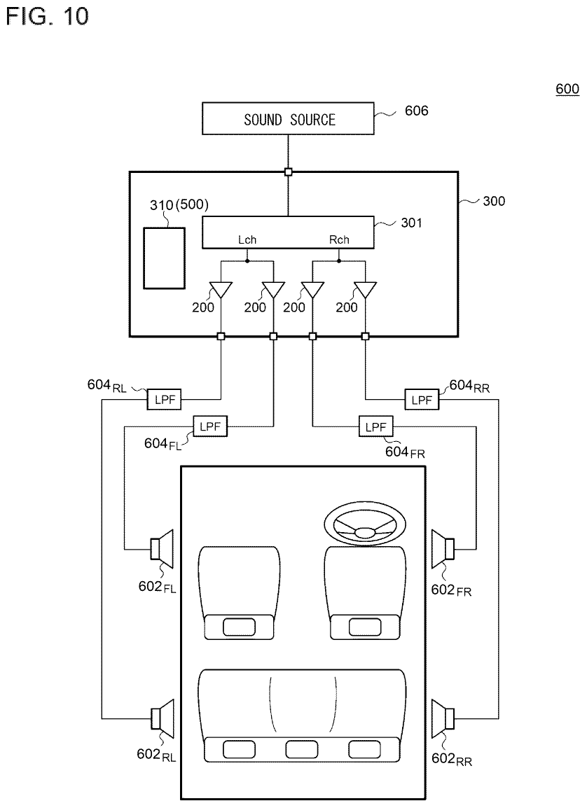

Description will be made regarding the usage of the audio circuit 300. FIG. 10 is a block diagram of an in-vehicle audio system using the audio circuit according to an embodiment.

An in-vehicle audio system 600 is provided with four speakers 602_{FL}, 602_{FR}, 602_{RL}, and 602_{RR}, four filters 604_{FL}, 604_{FR}, 604_{RF}, and 604_{RR}, a sound source 606, and an audio circuit 300.

The sound source 606 outputs two channels (left and right channels) or multiple channels of audio signals. The audio circuit 300 includes a four-channel Class-D amplifier circuit 200, an interface circuit 301 for a sound source 606, and a constant voltage circuit 310.

The filter 604, the sound source 606, and the audio circuit 300 are built into an audio head unit or car navigation apparatus. Also, the audio circuit 300 may be configured as a product that is independent of the sound source 606.

As described above, the audio circuit 300 (automotive integrated circuit 400) can be suitably employed in an in-vehicle electronic device or an in-vehicle device.

### Modifications

The above-described embodiments have been described for exemplary purposes only. Rather, it can be readily conceived by those skilled in this art that various modifications may be made by making various combinations of the aforementioned components or processes. Description will be made below regarding such modifications.

The clamp circuit 530 shown in FIG. 5 clamps the output node of the first voltage dividing circuit 510 and the output node of the second voltage dividing circuit 520 such that they do not exceed the common limit voltage V_{LIM}. However, the present invention is not restricted to such an arrangement. A modification may be made in which there is a difference in the clamp voltage for the clamp circuit 530 between the output node of the first voltage dividing circuit 510 and the output node of the second voltage dividing circuit 520.

### NOTES

The following techniques are disclosed in the present specification.

### Item 1

An automotive integrated circuit comprising:
a power supply terminal to be coupled to a battery;
a capacitor connection terminal to be coupled to an external capacitor;
a constant voltage circuit structured to stabilize a voltage that occurs at the capacitor connection terminal; and
an internal circuit structured to operate based on the voltage that occurs at the capacitor connection terminal,
wherein the constant voltage circuit comprises:
   a first voltage dividing circuit having an input node coupled to the power supply terminal and an output node coupled to the capacitor connection terminal, structured to generate a first voltage, which is obtained by dividing the power supply voltage that occurs at the power supply terminal, at the capacitor connection terminal;
   a charging transistor with one end coupled to the capacitor connection terminal;
   a second voltage dividing circuit having an input node coupled to the power supply terminal and an output node coupled to a control terminal of the charging transistor, structured to generate a second voltage obtained by dividing the power supply voltage at the control terminal of the charging transistor; and
   a clamp circuit structured to clamp the voltage generated at the capacitor connection terminal and the voltage at the control terminal of the charging transistor.

### Item 2

The automotive integrated circuit according to item 1, wherein the clamp circuit comprises:
a first transistor having an emitter coupled to the output node of the first voltage dividing circuit,
a second transistor having an emitter coupled to the output node of the second voltage dividing circuit; and
a first regulator circuit structured to apply a predetermined voltage to a base of each of the first transistor and the second transistor.

### Item 3

The automotive integrated circuit according to item 2, wherein the first transistor and the second transistor are each structured as a Darlington transistor.

### Item 4

The automotive integrated circuit according to item 2 or 3, wherein the first regulator circuit comprises:
an operational amplifier structured to receive a reference voltage via a non-inverting input terminal,
a first resistor coupled between an output of the operational amplifier and an inverting input terminal thereof; and
a second resistor coupled between the inverting input terminal of the operational amplifier and a ground.

### Item 5

The automotive integrated circuit according to any one of items 1 through 4, wherein the internal circuit comprises an audio amplifier structured to operate with a voltage that occurs at the capacitor connection terminal as a reference, so as to amplify an audio signal.

### Item 6

The automotive integrated circuit according to any one of items 1 through 3, wherein the constant voltage circuit further comprises a second regulator circuit arranged having an input node coupled to the power supply terminal and an output node coupled to the other end of the charging transistor and structured to output an internal power supply voltage stabilized to a predetermined voltage level.

### Item 7

The automotive integrated circuit according to item 6, wherein the second regulator circuit comprises:
a third transistor arranged with a drain coupled to the input node of the second regulator circuit and with a source coupled to the output node of the second regulator circuit,
a third resistor coupled between the output node of the second regulator and a ground,
a first Zener diode coupled between a gate and source of the third transistor; and
a bias circuit structured to apply a constant voltage to a gate of the third transistor.

### Item 8

The automotive integrated circuit according to item 7, wherein the bias circuit comprises:
a fourth resistor coupled between the input node of the second regulator circuit and the gate of the third transistor; and
a plurality of second Zener diodes coupled in series between the gate of the third transistor and a ground.

### Item 9

The automotive integrated circuit according to any one of items 1 through 3, wherein the other end of the charging transistor is coupled to the power supply terminal.

### Item 10

The automotive integrated circuit according to item 5, wherein the audio amplifier is structured as a Class-D amplifier circuit,
wherein the internal circuit further comprises a linear regulator structured to generate a first power supply voltage with a voltage that occurs at the capacitor connection terminal as a reference,
and wherein the Class-D amplifier circuit comprises:
   an inverter-type output stage structured to receive a supply of the power supply voltage,
an integrator structured to receive a supply of the first power supply voltage, and to receive a feedback signal that corresponds to an input audio signal and an output signal of the output stage,
a comparator structured to receive a supply of the first power supply voltage, and to convert an output of the integrator into a PWM signal; and
a driver structured to receive a supply of a second power supply voltage that is lower than the power supply voltage and the first power supply voltage, and to drive the output stage based on an output of the comparator.

### Item 11

An in-vehicle electronic device provided with the automotive integrated circuit according to any one of items 1 through 10.

What is claimed is:

1. An automotive integrated circuit comprising:
a power supply terminal to be coupled to a battery,
a capacitor connection terminal to be coupled to an external capacitor,
a constant voltage circuit structured to stabilize a voltage that occurs at the capacitor connection terminal; and
an internal circuit structured to operate based on the voltage that occurs at the capacitor connection terminal,
wherein the constant voltage circuit comprises:
a first voltage dividing circuit having an input node coupled to the power supply terminal and an output node coupled to the capacitor connection terminal, structured to generate a first voltage, which is obtained by dividing the power supply voltage that occurs at the power supply terminal, at the capacitor connection terminal,
a charging transistor with one end coupled to the capacitor connection terminal,
a second voltage dividing circuit having an input node coupled to the power supply terminal and an output node coupled to a control terminal of the charging transistor, structured to generate a second voltage obtained by dividing the power supply voltage at the control terminal of the charging transistor; and
a clamp circuit structured to clamp the voltage generated at the capacitor connection terminal and the voltage at the control terminal of the charging transistor.

2. The automotive integrated circuit according to claim 1, wherein the clamp circuit comprises:
a first transistor having an emitter coupled to the output node of the first voltage dividing circuit,
a second transistor having an emitter coupled to the output node of the second voltage dividing circuit; and
a first regulator circuit structured to apply a predetermined voltage to a base of each of the first transistor and the second transistor.

3. The automotive integrated circuit according to claim 2, wherein the first transistor and the second transistor are each structured as a Darlington transistor.

4. The automotive integrated circuit according to claim 2, wherein the first regulator circuit comprises:
an operational amplifier structured to receive a reference voltage via a non-inverting input terminal,
a first resistor coupled between an output of the operational amplifier and an inverting input terminal thereof; and
a second resistor coupled between the inverting input terminal of the operational amplifier and a ground.

5. The automotive integrated circuit according to claim 1, wherein the internal circuit comprises an audio amplifier structured to operate with a voltage that occurs at the capacitor connection terminal as a reference, so as to amplify an audio signal.

6. The automotive integrated circuit according to claim 1, wherein the constant voltage circuit further comprises a second regulator circuit arranged having an input node coupled to the power supply terminal and an output node coupled to the other end of the charging transistor and structured to output an internal power supply voltage stabilized to a predetermined voltage level.

7. The automotive integrated circuit according to claim 6, wherein the second regulator circuit comprises:
a third transistor arranged with a drain coupled to the input node of the second regulator circuit and with a source coupled to the output node of the second regulator circuit,
a third resistor coupled between the output node of the second regulator and a ground,
a first Zener diode coupled between a gate and source of the third transistor; and
a bias circuit structured to apply a constant voltage to a gate of the third transistor.

8. The automotive integrated circuit according to claim 7, wherein the bias circuit comprises:
a fourth resistor coupled between the input node of the second regulator circuit and the gate of the third transistor; and
a plurality of second Zener diodes coupled in series between the gate of the third transistor and a ground.

9. The automotive integrated circuit according to claim 1, wherein the other end of the charging transistor is coupled to the power supply terminal.

10. The automotive integrated circuit according to claim 5, wherein the audio amplifier is structured as a Class-D amplifier circuit,
wherein the internal circuit further comprises a linear regulator structured to generate a first power supply voltage with a voltage that occurs at the capacitor connection terminal as a reference,
and wherein the Class-D amplifier circuit comprises:
an inverter-type output stage structured to receive a supply of the power supply voltage,
an integrator structured to receive a supply of the first power supply voltage, and to receive a feedback signal that corresponds to an input audio signal and an output signal of the output stage,
a comparator structured to receive a supply of the first power supply voltage, and to convert an output of the integrator into a PWM signal; and
a driver structured to receive a supply of a second power supply voltage that is lower than the power supply voltage and the first power supply voltage, and to drive the output stage based on an output of the comparator.

11. An in-vehicle electronic device provided with the automotive integrated circuit according to claim 1.
